(19) United States
(12) Patent Application Publication
(10) Pub. No.: US 2026/0003140 A1
(43) Pub. Date: Jan. 1, 2026

(54) ELECTRONIC PACKAGE

(71) Applicant: SILICONWARE PRECISION INDUSTRIES CO., LTD., Taichung City (TW)

(72) Inventors: Chung-Yu KE, Taichung City (TW); Liang-Pin CHEN, Taichung City (TW)

(73) Assignee: SILICONWARE PRECISION INDUSTRIES CO., LTD., Taichung City (TW)

(21) Appl. No.: 18/958,239

(22) Filed: Nov. 25, 2024

(30) Foreign Application Priority Data
Jul. 1, 2024 (TW) 113124546

(51) Int. Cl. G02B 6/42; H01L 23/367; H01L 25/16

(52) U.S. Cl. CPC G02B 6/4246; G02B 6/4212; G02B 6/4268; H01L 23/3675; H01L 25/167

(57) ABSTRACT

An electronic package includes a carrier structure, an optoelectronic module, at least a first transceiver module, a first semiconductor component, and a heat dissipation component. The optoelectronic module is disposed on and electrically connected to the carrier structure, and includes an optoelectronic component and a first encapsulating layer covering the optoelectronic component. The first transceiver module includes a first optical signal transmission unit. The first semiconductor component is disposed on and electrically connected to the carrier structure. The heat dissipation component is connected to the first semiconductor component, and the first transceiver module is coupled to the heat dissipation component. Hence, the number of optical fibers connected to the electronic package can be increased, so the amount of data that can be received and transmitted by the electronic package per unit time can be greatly increased, thereby significantly improving data transmission and processing speed of the electronic package.

### BACKGROUND

### 1. Technical Field

The present disclosure relates to a semiconductor device, and more particularly, to an electronic package having a photonic component.

### 2. Description of Related Art

After experiencing the evolution of generations such as personal computers, mobile communications and artificial intelligence (AI), etc., and stimulated by changes in life and culture such as mobile internet, online shopping, video streaming and online games, modern communication technology has become increasingly demanding for communication bandwidth, so optical fibers have begun to replace copper cables in large numbers.

In response to the above-mentioned trends and developments, the semiconductor industry has also developed various semiconductor components for optical fiber communications to connect with the optical fibers and receive and transmit optical signals through the optical fibers for the transmission of large amounts of data. However, since existing semiconductor components used in optical communications are limited by their packaging technology and structure, most of them can only connect to one optical fiber, therefore the transmission speed (i.e., the amount of data transmission per unit time) of existing optical fiber communications has encountered a bottleneck and is gradually insufficient, let alone coping with the rapid and substantial growth in data transmission needs of future technologies and products.

Therefore, how to overcome the above-mentioned problems of the prior art has become an urgent issue to be solved.

### SUMMARY

In view of the aforementioned shortcomings of the prior art, the present disclosure provides an electronic package, which comprises: a carrier structure; an optoelectronic module disposed on and electrically connected to the carrier structure, wherein the optoelectronic module includes an optoelectronic component and a first encapsulating layer encapsulating the optoelectronic component; a first semiconductor component disposed on and electrically connected to the carrier structure; a heat dissipation component coupled to the first semiconductor component; and at least one first transceiver module including a first optical signal transmission unit and coupled to the heat dissipation component, wherein the at least one first transceiver module is coupled to at least one first optical fiber and receives and transmits optical signals from the at least one first optical fiber, wherein the first optical signal transmission unit is located between the at least one first optical fiber and the optoelectronic component for receiving and transmitting the optical signals.

In the aforementioned electronic package, the at least one first transceiver module protrudes upward and is exposed from the heat dissipation component.

In the aforementioned electronic package, the optoelectronic component includes at least one first coupler, and the at least one first coupler corresponds to the first optical signal transmission unit.

The aforementioned electronic package further comprises at least one second transceiver module coupled to the heat dissipation component, wherein the at least one second transceiver module is coupled to at least one second optical fiber and receives and transmits optical signals from the at least one second optical fiber, wherein the at least one second transceiver module includes a second optical signal transmission unit, and the second optical signal transmission unit is located between the at least one second optical fiber and the optoelectronic component for receiving and transmitting the optical signals.

In the aforementioned electronic package, the optoelectronic component includes at least one first coupler, and the at least one first coupler corresponds to the first optical signal transmission unit and the second optical signal transmission unit.

In the aforementioned electronic package, the optoelectronic component includes at least one first coupler and at least one second coupler, wherein the at least one first coupler corresponds to the first optical signal transmission unit, and the at least one second coupler corresponds to the second optical signal transmission unit.

In the aforementioned electronic package, the optoelectronic component is a photonic integrated circuit.

In the aforementioned electronic package, the first semiconductor component is an electronic integrated circuit.

In the aforementioned electronic package, the at least one first transceiver module includes a fiber array unit.

In the aforementioned electronic package, the first optical signal transmission unit includes a total internal reflector.

In the aforementioned electronic package, the optoelectronic module further includes

a second semiconductor component.

In the aforementioned electronic package, the second semiconductor component is an electronic integrated circuit.

In the aforementioned electronic package, the second optical signal transmission unit includes a waveguide array.

In the aforementioned electronic package, the at least one second transceiver module is coupled to a bottom side of a top portion of the heat dissipation component.

It can be seen from the above that in the electronic package of the present disclosure, multiple transceiver modules for receiving and transmitting optical signals are provided, and each of the transceiver modules can be connected to multiple optical fibers, so the amount of data that can be received and transmitted by the electronic package per unit time can be greatly increased, thereby significantly improving the data transmission speed and data processing speed of the electronic package.

### BRIEF DESCRIPTION OF THE DRAWINGS

FIG. 1-1 is a schematic cross-sectional view of an embodiment of the present

### DISCLOSURE

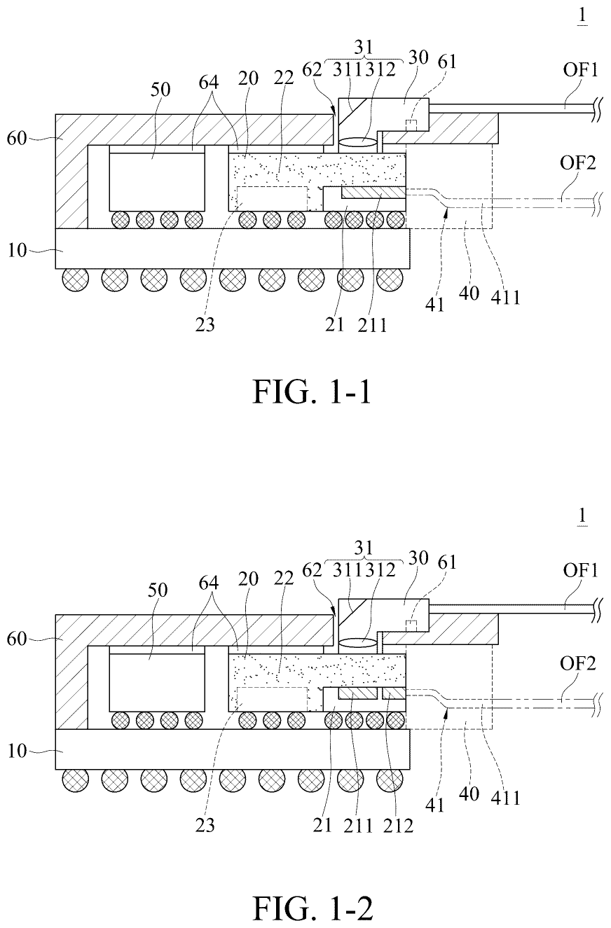

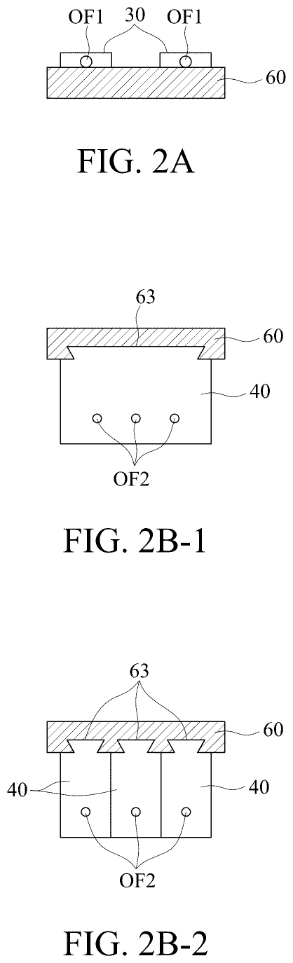

FIG. 1-2 is a schematic cross-sectional view of another embodiment of the present disclosure.

FIG. 2A is a schematic front view of a first transceiver module and a heat dissipation component.

FIG. 2B-1 is a schematic front view of a second transceiver module and the heat dissipation component.

FIG. 2B-2 is a schematic front view of a variant aspect of a second transceiver module and a heat dissipation component.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

FIG. 1-1 is a schematic cross-sectional view of an embodiment of an electronic package 1 of the present disclosure. As shown in FIG. 1-1, this embodiment provides an electronic package 1, which includes a carrier structure 10, an optoelectronic module 20, at least one first transceiver module 30 (a transmitting and receiving module), a first semiconductor component 50, and a heat dissipation component 60.

The carrier structure 10 is a substrate, such as a silicon substrate, a glass substrate, or a circuit board. A circuit layer or multiple circuit layers (not shown), such as a redistribution layer (RDL) or multiple redistribution layers, may be formed within the carrier structure 10. The configuration of the carrier structure 10 depends on the needs of applications and/or design, and there is no restriction made by this embodiment.

The optoelectronic module 20 is disposed on the carrier structure 10 and is electrically connected to the carrier structure 10. For instance, if one or more circuit layers are included in the carrier structure 10 as described above, the optoelectronic module 20 can be electrically connected to one or more of the circuit layers. The optoelectronic module 20 includes an optoelectronic component 21, and the optoelectronic component 21 is covered by a first encapsulating layer 22, thereby forming an encapsulation module. The optoelectronic component 21 is, for example, a photonic integrated circuit (PIC), whose function is to convert optical signals into electronic signals, or vice versa.

The first transceiver module 30 includes a first optical signal transmission unit 31 therein and is firmly connected to one or more first optical fibers OF1 via a structure such as a guiding tube (not shown), and the first optical signal transmission unit 31 corresponds to the first optical fiber(s) OF1 so as to transmit optical signals mutually. If the first transceiver module 30 is connected to multiple first optical fibers OF1, a fiber array unit (FAU) may be included within the first transceiver module 30 so as to connect to the first optical fibers OF1.

The first optical signal transmission unit 31 may include a total internal reflector, a waveguide, a waveguide array, or an arbitrary combination of these components, so that the optical signals received from the first optical fiber(s) OF1 are transmitted to the optoelectronic component 21 in the optoelectronic module 20 via the first optical signal transmission unit 31 of the first transceiver module 30, and then the optical signals are converted into electronic signals via the optoelectronic component 21. In this embodiment, a total internal reflector 311 disposed in the first optical signal transmission unit 31 is used as an example.

The first semiconductor component 50 is disposed on the carrier structure 10 and is electrically connected to the carrier structure 10. The first semiconductor component 50 is an electronic IC (EIC), for example, the choice of which all depends on the requirement of function and/or the design of the circuit, and is without any special restriction.

The heat dissipation component 60 may be connected to the first semiconductor component 50 via a thermal interface material (TIM) layer 64, and the heat dissipation component 60 may also be connected to the optoelectronic module 20 via a TIM layer 64, so that the heat generated during the operation of the first semiconductor component 50 and the optoelectronic module 20 can be dissipated into the outer environment. The heat dissipation component 60 is fixed on the carrier structure 10, and the first transceiver module 30 is connected to and fixed on the heat dissipation component 60.

In this embodiment, the first transceiver module 30 is engaged with and fixed on the top of the heat dissipation component 60 via a tenon 61, and the first transceiver module 30 protrudes upward and is exposed from the heat dissipation component 60. Certainly, the first transceiver module 30 can also be fixed on the heat dissipation component 60 via other types of fixture structure or fixing method, and this embodiment does not impose particular limitation.

An opening 62 is set on the heat dissipation component 60 for the transmission of optical signals between the total internal reflector 311 and the optoelectronic component 21. In this embodiment, an optical signal travels to the total internal reflector 311 in the first optical signal transmission unit 31 first after the optical signal has transmitted into the first transceiver module 30 from the first optical fiber OF1; then, the optical signal, travelling along a horizontal direction, is reflected via the total internal reflector 311 by way of total internal reflection (TIR), so that the optical signal travels along a vertical direction and toward the optoelectronic component 21. Further, a collimating lens 312 can be disposed between the total internal reflector 311 and the optoelectronic component 21, such that the optical signal can aim the optoelectronic component 21 properly and propagate to the optoelectronic component 21. Next, the optoelectronic component 21 converts the received optical signal into an electronic signal, then transmits the converted electronic signal to the first semiconductor component 50 via the electrical connection between the optoelectronic module 20 and the carrier structure 10 to perform the subsequent processing. This is the reception process of the signals. Certainly, the electronic signal generated by the first semiconductor component 50 can be converted into an optical signal and then be transmitted out via an optical fiber, so that a signal transmission can be performed via a reverse path and process, which will not be described more here.

More specifically, the optoelectronic component 21 includes at least one first coupler 211 therein. The first coupler 211 corresponds to the first optical signal transmission unit 31 and the first optical fiber OF1 firmly connected to the first optical signal transmission unit 31. After the optical signal has travelled through the total internal reflector 311 and the collimating lens 312 in the first optical signal transmission unit 31 from the first optical fiber OF1, the optical signal projects into the first coupler 211 of the optoelectronic component 21 and is received by the first coupler 211. Conversely, when the signal is going to be transmitted, the electronic signal is converted into an optical signal within the optoelectronic component 21 first, then the converted optical signal is emitted from the first coupler 211 and travels along the aforementioned path but in an opposite direction via the collimating lens 312, the total internal reflector 311 and the first optical fiber OF1 so as to be outputted.

The number of the first coupler 211 may be one or more. For instance, if there is only one first transceiver module 30 and if only one first optical fiber OF1 is connected to the first transceiver module 30, then only one first coupler 211 is needed to be set within the optoelectronic component 21 naturally. But if there is only one first transceiver module 30 and it is connected to a plurality of first optical fibers OF1, or if there are a plurality of first transceiver modules 30 and each of them is connected to a first optical fiber OF1 respectively as shown in FIG. 2A, the optoelectronic component 21 may be provided with only one first coupler 211 that is capable of receiving/transmitting optical signals from/to all the first optical fibers OF1, or the optoelectronic component 21 may be provided with a plurality of first couplers 211 that are capable of receiving/transmitting optical signals from/to different first optical fibers OF1 respectively (for instance, each of the plurality of first couplers 211 can receive/transmit an optical signal from/to a different one of the first optical fibers OF1 respectively). All of the configurations described above are adoptable. The actual way adopted to configure the first coupler 211 depends on the design and/or functional requirements, and is not specific.

In addition, the electronic package 1 provided in this embodiment can further include at least one second transceiver module 40 (a transmitting and receiving module). The second transceiver module 40 is also firmly connected to the heat dissipation component 60. In this embodiment, one side of the top portion of the heat dissipation component 60 protrudes outward into an outside of the carrier structure 10, while the second transceiver module 40 is mechanically connected to the bottom of the part of the top portion of the heat dissipation component 60 that protrudes from the carrier structure 10, and the second transceiver module 40 can be fixed to the bottom of the part of the top portion of the heat dissipation component 60 that protrudes from the carrier structure 10 via a structure such as a sliding groove 63 as shown in FIG. 2B-1 or FIG. 2B-2.

Similarly, the second transceiver module 40 can be firmly connected to one or more second optical fibers OF2, and the second transceiver module 40 includes a second optical signal transmission unit 41. The second optical signal transmission unit 41 is located between the one or more second optical fibers OF2 and the optoelectronic component 21, such that optical signals can be transmitted between the second optical fiber(s) OF2 and the optoelectronic component 21, so that the optoelectronic component 21 is able to convert the optical signals into electronic signals and then transmit the electronic signals to the first semiconductor component 50, or the optoelectronic component 21 is able to convert the electronic signals that come from the first semiconductor component 50 into optical signals and to transmit the optical signals to the second transceiver module 40 via the second optical signal transmission unit 41 so that the optical signals can be emitted via the second optical fiber(s) OF2.

The second optical signal transmission unit 41 can also include a total internal reflector, a waveguide, a waveguide array 411, or an arbitrary combination of those components, wherein a waveguide array 411 is used as an example in this embodiment. The mechanism and the process in which the electronic package 1 receives and transmits signals via the optoelectronic module 20 and the second transceiver module 40 are almost identical to the aforementioned principles, mechanism and process in which the signals are received and transmitted via the optoelectronic module 20 and the first transceiver module 30, so they will not be described repeatedly here either.

In an aspect of embodiment, as shown in FIG. 1-2, at least one second coupler 212 can be disposed in the optoelectronic module 20. Similarly, the arrangements of the second coupler(s) 212 include: one second coupler 212 corresponds to one second transceiver module 40, one second coupler 212 corresponds to a plurality of second transceiver modules 40, a plurality of second couplers 212 correspond to a plurality of second transceiver modules 40 (as shown in FIG. 2B-2) respectively, etc. The arrangements of the second coupler(s) 212 will not be repeatedly described here.

In addition, in some variant aspects of embodiment, the optoelectronic module 20 can further include a second semiconductor component 23 therein. The second semiconductor component 23 may also be an electronic IC. Because the second semiconductor component 23 is also disposed in the optoelectronic module 20 and is closer to the optoelectronic component 21 in distance, therefore the second semiconductor component 23 can process the electronic signals that come in and out from the optoelectronic component 21 more quickly. Or, the second semiconductor component 23 may also be a memory component and can be used as a buffer for the electronic signals that come in and out from the optoelectronic component 21. This embodiment has no restriction for this.

In summary, in the electronic package of the present disclosure, one or more first transceiver modules and/or one or more second transceiver modules are disposed on the heat dissipation component, and each of the first transceiver modules or the second transceiver modules can be connected to one or more optical fibers (including the first optical fiber(s) and the second optical fiber(s)), so the amount of data that can be received and transmitted by the electronic package per unit time can be greatly increased, thereby significantly improving the data transmission speed and data processing speed of the electronic package.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrier structure;
an optoelectronic module disposed on and electrically connected to the carrier structure, wherein the optoelectronic module includes an optoelectronic component and a first encapsulating layer covering the optoelectronic component;
a first semiconductor component disposed on and electrically connected to the carrier structure;
a heat dissipation component coupled to the first semiconductor component; and
at least one first transceiver module including a first optical signal transmission unit and attached to the heat dissipation component, wherein the at least one first transceiver module is coupled to at least one first optical fiber for receiving and transmitting optical signals from the at least one first optical fiber, and the first optical signal transmission unit is located between the at least one first optical fiber and the optoelectronic component for receiving and transmitting the optical signals.

2. The electronic package of claim 1, wherein the at least one first transceiver module protrudes upward and is exposed from the heat dissipation component.

3. The electronic package of claim 1, wherein the optoelectronic component includes at least one first coupler, and the at least one first coupler corresponds to the first optical signal transmission unit.

4. The electronic package of claim 1, further comprising at least one second transceiver module coupled to the heat dissipation component, wherein the at least one second transceiver module is coupled to at least one second optical fiber and receives and transmits optical signals from the at least one second optical fiber, wherein the at least one second transceiver module includes a second optical signal transmission unit, and the second optical signal transmission unit is located between the at least one second optical fiber and the optoelectronic component for receiving and transmitting the optical signals.

5. The electronic package of claim 4, wherein the optoelectronic component includes at least one first coupler, and the at least one first coupler corresponds to the first optical signal transmission unit and the second optical signal transmission unit.

6. The electronic package of claim 4, wherein the optoelectronic component includes at least one first coupler and at least one second coupler, wherein the at least one first coupler corresponds to the first optical signal transmission unit, and the at least one second coupler corresponds to the second optical signal transmission unit.

7. The electronic package of claim 4, wherein the second optical signal transmission unit includes a waveguide array.

8. The electronic package of claim 4, wherein the at least one second transceiver module is coupled to a bottom side of a top portion of the heat dissipation component.

9. The electronic package of claim 1, wherein the optoelectronic component is a photonic integrated circuit.

10. The electronic package of claim 1, wherein the first semiconductor component is an electronic integrated circuit.

11. The electronic package of claim 1, wherein the at least one first transceiver module includes a fiber array unit.

12. The electronic package of claim 1, wherein the first optical signal transmission unit includes a total internal reflector.

13. The electronic package of claim 1, wherein the optoelectronic module further includes a second semiconductor component.

14. The electronic package of claim 13, wherein the second semiconductor component is an electronic integrated circuit.
